(19) United States
(12) Patent Application Publication
(10) Pub. No.: US 2011/0140192 A1
(43) Pub. Date: Jun. 16, 2011

(54) METHOD FOR MANUFACTURING TWIN BIT STRUCTURE CELL WITH FLOATING POLYSILICON LAYER

(75) Inventor: MIENO FUMITAKE, Shanghai (CN)

(73) Assignee: Semiconductor Manufacturing International (Shanghai) Corporation, Shanghai (CN)

(21) Appl. No.: 12/969,563

(22) Filed: Dec. 15, 2010

(30) Foreign Application Priority Data
Dec. 15, 2009 (CN) 200910201191.7

(51) Int. Cl. H01L 29/792; H01L 21/336

(52) U.S. Cl. 257/324; 438/287; 257/E29.309; 257/E21.423

(57) ABSTRACT

A method for forming a twin-bit cell structure is provided. The method includes providing a semiconductor substrate including a surface region. A gate dielectric layer is formed overlying the surface region. The method forms a polysilicon gate structure overlying the gate dielectric layer. In a specific embodiment, the method subjects the gate polysilicon structure to an oxidizing environment to cause formation of a first silicon oxide layer overlying the gate polysilicon structure. Preferably, an undercut region is allowed to be formed underneath the gate polysilicon structure. The method includes forming an undoped polysilicon material overlying the polysilicon gate structure including the undercut region and the gate dielectric layer. The undoped polysilicon material is subjected to a selective etching process to form an insert region in a portion of the undercut region while the insert region remains filled with the undoped polysilicon material.

### CROSS-REFERENCES TO RELATED APPLICATIONS

This application claims priority to Chinese Patent Application No. 200910201191.7; filed Dec. 15, 2009; commonly assigned, and incorporated herein by reference for all purposes.

### BACKGROUND OF THE INVENTION

The present invention is directed to integrated circuits and their processing for the manufacture of semiconductor devices. More particularly, the invention provides a method and a device for forming a twin-bit cell structure for semiconductor integrated circuit devices, but it would be recognized that the invention has a much broader range of applicability. In a specific embodiment, undoped polysilicon material is used to hold charges in a twin-bit structure.

Integrated circuits have evolved from a handful of interconnected devices fabricated on a single chip of silicon to millions of devices. Conventional integrated circuits provide performance and complexity far beyond what was originally imagined. In order to achieve improvements in complexity and circuit density (i.e., the number of devices capable of being packed onto a given chip area), the size of the smallest device feature, also known as the device “geometry”, has become smaller with each generation of integrated circuits.

Increasing circuit density has not only improved the complexity and performance of integrated circuits but has also provided lower cost parts to the consumer. An integrated circuit or chip fabrication facility can cost hundreds of millions, or even billions, of U.S. dollars. Each fabrication facility will have a certain throughput of wafers, and each wafer will have a certain number of integrated circuits on it. Therefore, by making the individual devices of an integrated circuit smaller, more devices may be fabricated on each wafer, thus increasing the output of the fabrication facility. Making devices smaller is very challenging, as each process used in integrated fabrication has a limit. That is to say, a given process typically only works down to a certain feature size, and then either the process or the device layout needs to be changed. An example of such limitation lies in manufacture of memory devices. As feature size continues to shrink, a twin bit cell structure becomes difficult to apply as it is difficult to control the gates independently.

One of the challenges in semiconductor has been the processing of manufacturing twin-bit cell structure for non-volatile memory devices, such as popular flash based memory devices. Among other things, the conventional system and method for manufacturing cells with twin-bit structures are limited when it is required to scaling down the cell size.

From the above, it is seen that an improved technique for manufacturing of devices having twin-bit cell structures is desired.

### BRIEF SUMMARY OF THE INVENTION

According to embodiments of the present invention, techniques directed to manufacturing of memory devices are provided. More particularly, embodiments according to the present invention provide a method and a structure for manufacturing a twin bit cell structure for a non-volatile memory device. But it should be recognized that the present invention has a much broader range of applicability.

In a specific embodiment, a method for forming a non-volatile memory structure is provided. The method includes providing a semiconductor substrate including a surface region. A gate dielectric layer is formed overlying the surface region. The method forms a polysilicon gate structure overlying the gate dielectric layer. In a specific embodiment, the method subjects the polysilicon gate structure to an oxidizing environment to cause formation of a first silicon oxide layer overlying the polysilicon gate structure. Preferably, an undercut region is allowed to be formed underneath the polysilicon gate structure. The method includes forming an undoped polysilicon material overlying the polysilicon gate structure including the undercut region and the gate dielectric layer. The undoped polysilicon material is subjected to a selective etching process to form an insert region in a portion of the undercut region while the insert region remains filled with the undoped polysilicon material.

According to another embodiment, the present invention provides a non-volatile memory device. In an embodiment, the non-volatile memory device includes a semiconductor substrate including a surface region, a gate dielectric layer overlying the surface region, a polysilicon gate structure overlying the gate dielectric layer. The non-volatile memory device also has a first undercut region underneath the polysilicon gate structure in a portion of the gate dielectric layer and a first silicon oxide layer covering an underside of the polysilicon gate structure facing the undercut region. Moreover, the non-volatile memory device also includes an undoped polysilicon material in an insert region in a portion of the undercut region and a sidewall structure overlying a side region of the polysilicon gate structure and a side region of the undoped polysilicon material.

Many benefits are achieved by ways of the present invention over conventional techniques. For example, embodiments according to the present invention provide a method to form a reliable twin-bit cell structure. According to a specific embodiment, a gate structure is formed on top of a dielectric layer, which is later selectively etched to form undercut regions. The undercut regions are used to accommodative conductive materials such as undoped polysilicon material. For example, the conductive material is used to hold charges to stores bits. It is to be appreciated that because of the innovation afforded by the present invention to provide undercut regions, various etching processes according to the present invention are self-aligned. Among other things, the technique according to the present invention for forming twin-bit device allows further scaling down of the device in comparison of convention techniques. Furthermore, various processes and techniques can be compatible with conventional systems and equipments, thereby allow cost effective implementation. There are other benefits as well.

Various additional objects, features and advantages of the present invention can be more fully appreciated with reference to the detailed description and accompanying drawings that follow.

### BRIEF DESCRIPTION OF THE DRAWINGS

FIG. 1 is a simplified flow diagram illustrating a conventional method of forming a gate structure for a non-volatile memory device.

FIG. 2 is a simplified flow diagram illustrating a method of forming a gate structure for a non-volatile memory device according to an embodiment of the present invention.

FIG. 3-11 are simplified diagrams illustrating a method of forming a gate structure for a non-volatile memory device according to an embodiment of the present invention.

### DETAILED DESCRIPTION OF THE INVENTION

According to embodiments of the present invention, techniques directed to manufacturing memory devices are provided. Merely by ways of example, embodiments according to the present invention provide a method and a structure for manufacturing a twin bit cell structure for a non-volatile memory device. But embodiments according to the present invention can be applied to manufacturing of other devices.

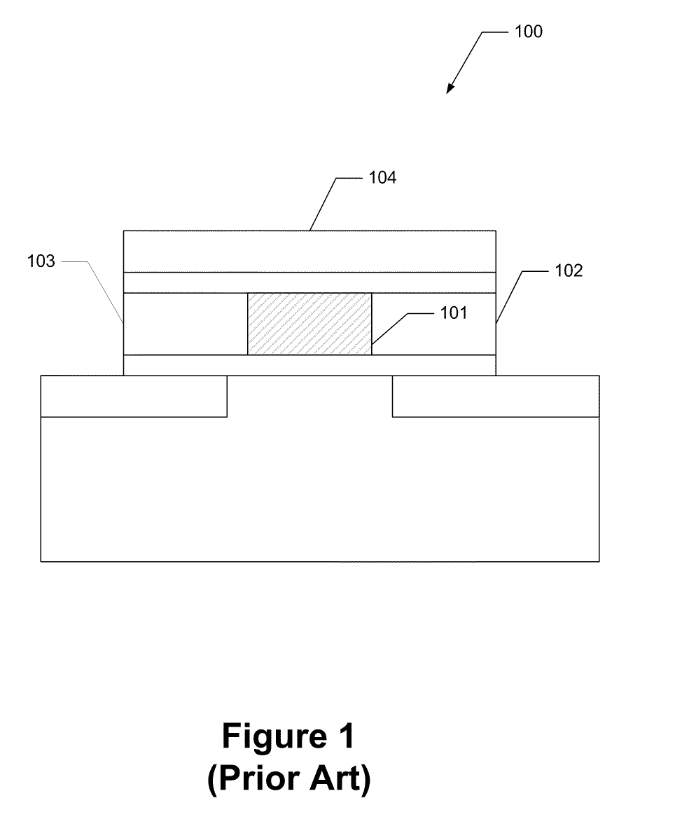

FIG. 1 is a simplified twin bit cell structure using a conventional method for fabrication. As shown in FIG. 1, the twin-bit structure 100 has two conductive regions 102 and 103 that can be configured to hold charges. The two conductive regions are separated by an isolation region 101. A control gate 104 overlays the conductive regions.

As an example, the twin bit cell structure shown in FIG. 1 is manufactured using the following steps:
1. provide a p-type substrate;
2. form a gate oxide layer overlaying the substrate;
3. perform low-pressure chemical vapor deposition (LPCVD) to form an n-type doped polysilicon layer;
4. perform high temperature oxidation (HTO) to anneal the doped polysilicon layer;
5. provide a layer of undoped polysilicon material;
6. perform HTO on the layer of undoped polysilicon material; and
7. form layer of n-type doped polysilicon material.

Among other things, the conventional manufacturing processes, such as the one outlined above, are difficult to achieve small scale. For example, the formation of an insulating region between the conducting layers (e.g., as provided by the n-type doped regions) is performed by an etching process that can only be scaled down so much. In addition, the use of multiple HTO processes imposes a limitation on the total available thermal budget.

Therefore, it is to be appreciated that various manufacturing processes and structures as provided by the embodiments of the present invention enable the down-scaling of the twin-bit cell structure size as compared to conventional techniques. An exemplary process is described in detail below.

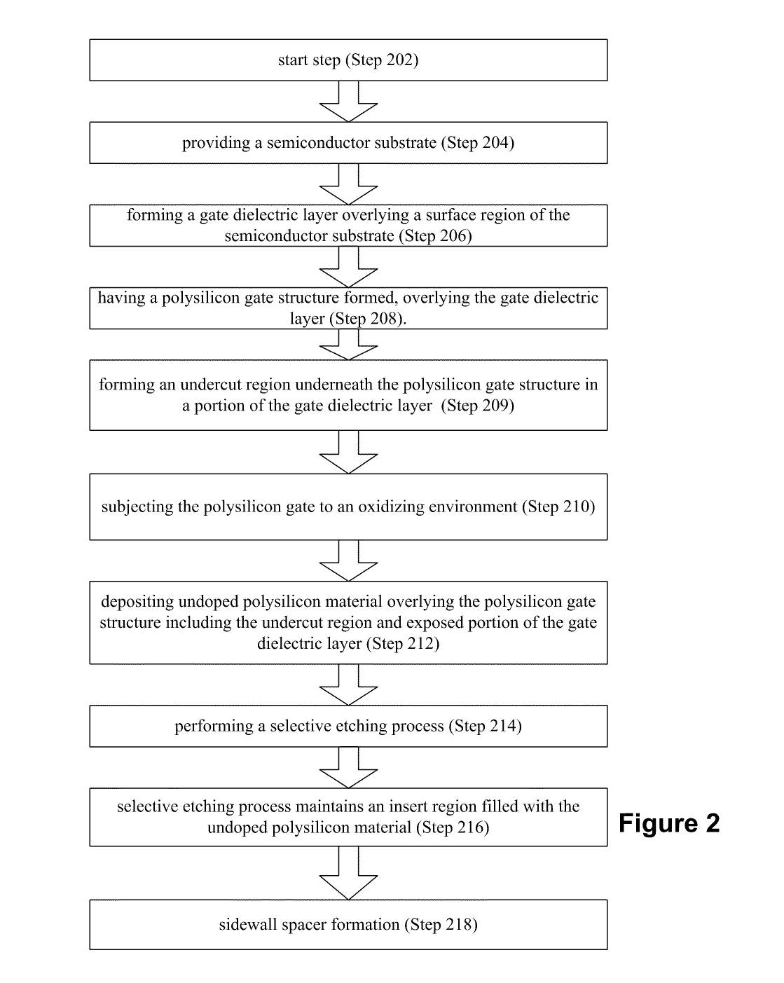

FIG. 2 is a simplified flow diagram illustrating a method of forming a twin-cell structure according to an embodiment of the present invention. This diagram is merely an example and should not unduly limit the claims herein. One skilled in the art would recognized other variations, modifications, and alternatives. As an example, various steps described in FIG. 2 can be added, removed, modified, replaced, repeated, rearranged, and/or overlapped.

As shown, the method has a start step (Step 202). The method includes providing a semiconductor substrate (Step 204). In a specific embodiment, the semiconductor substrate is a single crystal silicon doped with a P-type impurity. Alternatively, the semiconductor substrate can be a silicon on insulator substrate, commonly known as SOI. The semiconductor substrate can also be a silicon germanium wafer or others, depending on the embodiment.

The method includes forming a gate dielectric layer overlying a surface region of the semiconductor substrate (Step 206). Depending on the application, the gate dielectric layer can formed in various ways, such as silicon oxide deposited using a suitable technique, for example, a thermal growth process. In a specific embodiment, a high temperature oxidation process is used to form a silicon oxide layer of less than 250 angstroms in thickness, which is to be used as the gate oxide layer.

The method further includes having a polysilicon gate structure formed, overlying the gate dielectric layer (Step 208). As an example, the polysilicon gate structure is formed by using a deposition process of a doped polysilicon material followed by a patterning and etch process. In a specific embodiment, an LPCVD process is used to form the polysilicon gate layer of less than 1000 angstroms. For example, silane may be used as a reactant gas to perform LPCVD.

In Step 209, an undercut region is formed underneath the polysilicon gate structure in a portion of the gate dielectric layer. In a specific embodiment, this step can be carried out by subjecting the device structure to an isotropic dielectric etching process. As an example, a wet HF etching process can be used. In another example, an isotropic dry dielectric etching process can be used.

As shown in FIG. 2, the method includes subjecting the polysilicon gate to an oxidizing environment (Step 210). In a specific embodiment, the oxidizing environment causes a silicon oxide layer to form surrounding the polysilicon gate structure and forms an undercut region in the gate dielectric layer.

The method then deposits an undoped polysilicon material overlying the polysilicon gate structure including the undercut region and exposed portion of the gate dielectric layer (Step 212). According to an embodiment, the undoped polysilicon material is deposited using chemical vapor deposition process. For example, underlying structure is subjected to silane gas at a temperature of approximately 400 to 500 degrees Celsius.

The method performs a selective etching process (Step 214) to remove a portion the undoped polysilicon material. In a preferred embodiment, the selective etching process maintains an insert region filled with the undoped polysilicon material (Step 216). For example, the gate oxide layer determines the thickness of the undoped polysilicon material.

The method performs other processes to complete the cell structure. For example, these other processes can include sidewall spacer formation (Step 218), among others. The method also includes performing other steps to complete the memory device. Of course, there can be other modifications, variations, and alternatives.

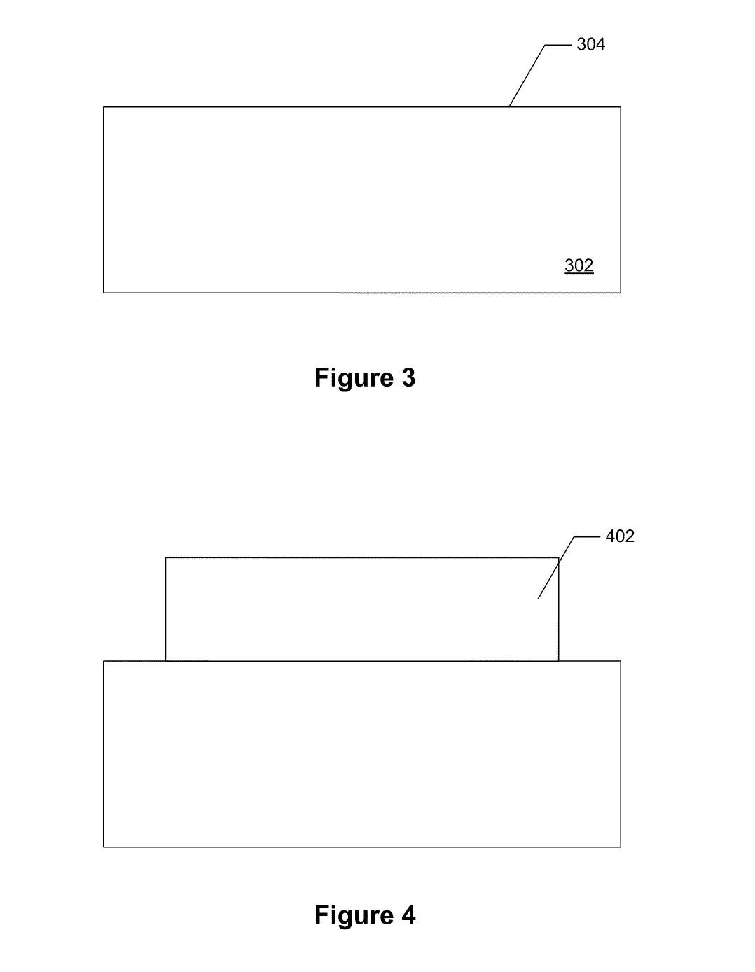

FIGS. 3-11 are simplified diagrams illustrating a method for forming a twin bit cell structure for a memory device according to an embodiment of the present invention. These diagrams are merely examples and should not unduly limit the claims herein. One skilled in the art would recognized other variations, modifications, and alternatives. It is to be appreciated various steps as illustrated in these figures can be performed in various sequences, repeated, modified, rearranged, and/or overlapped.

As shown in FIG. 3, the method provides a semiconductor substrate 302. The semiconductor substrate can be a single crystal silicon substrate doped with a P-type impurity in a specific embodiment. Alternatively, the semiconductor substrate can be a silicon on insulator substrate, commonly known as SOI. The semiconductor substrate can also be a silicon germanium wafer or others, depending on the embodiment. As shown, the semiconductor substrate includes a surface region 304.

In a specific embodiment, the method includes forming a gate dielectric layer 402 overlying the surface region of the semiconductor substrate as shown in FIG. 4. The gate dielectric layer can be a high density silicon oxide layer formed by a thermal growth process. The gate dielectric layer can also be a composite dielectric stack, for example, silicon oxide on silicon nitride on silicon oxide stack, commonly known as ONO. Other dielectric materials such as silicon nitride, silicon oxynitride, may also be used, depending on the embodiment. Taking a thermally grown oxide as the gate dielectric layer as an example, the gate dielectric can have a thickness ranging from about 20 angstroms to about 1000 angstroms. In a specific embodiment, high temperature oxidation process is used to form the gate dielectric layer 402 consisting mostly silicon oxide, the dielectric layer 402 having a thickness of between 50 to 1000 angstroms. Of course there can be other variations, modifications, and alternatives.

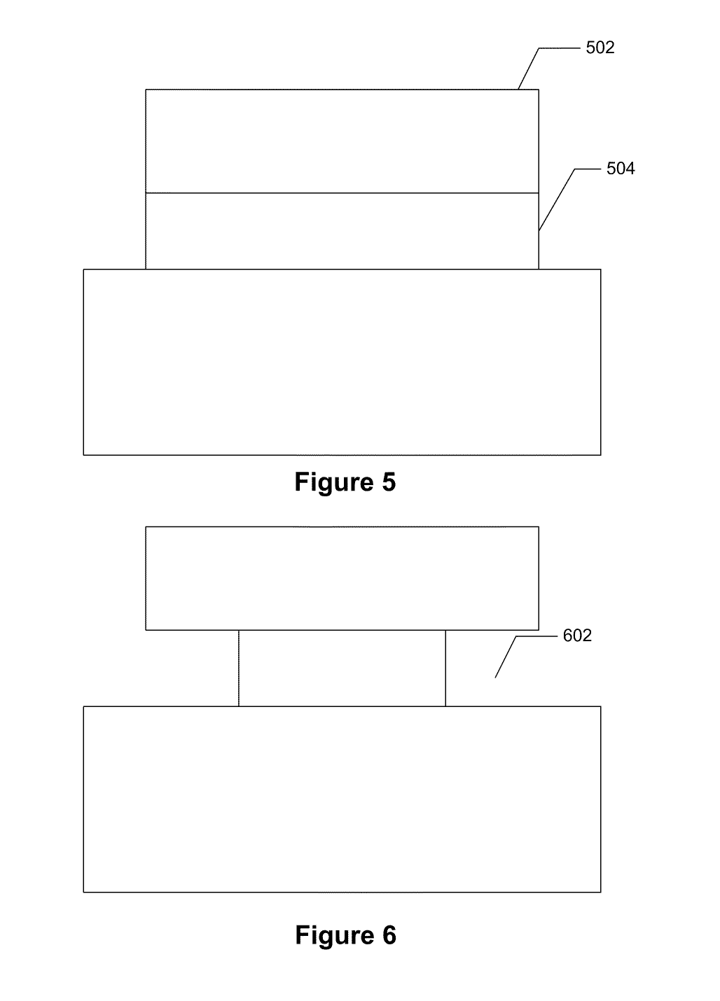

Referring to FIG. 5, the method includes forming a gate structure 502 overlying the gate dielectric layer 504. In a specific embodiment, the gate structure can be a polysilicon gate structure. The polysilicon gate structure can be formed by a deposition of a polysilicon material followed by a pattern and etch process. For example, LPCVD process is used to form the polysilicon gate structure. The polysilicon material may be doped with suitable impurities to provide for a desirable property. In a specific embodiment, the polysilicon material is doped with N-type impurities such as arsenic, phosphorus, or antimony, but can be others. For example, the doping concentration of the N-type impurities is approximately between 1.0E18 and 1.0E22 atoms/cm³. Depending on the specific applications, the gate structure 502 may have a thickness of between 300 to 5,000 angstroms. In a preferred embodiment, the gate structure has a doping concentration of about 1.0E20 atoms/cm³ and a thickness of about 1000 angstroms.

In a specific embodiment, the method forms a first undercut region 602 in a portion of the gate dielectric layer as shown in FIG. 6. The undercut region can be formed using a self-limiting etching process in a specific embodiment. For example, the size of the undercut region depends at least on the thickness of the polysilicon layer. In a specific embodiment, a selective etching process is performed to partially remove the gate dielectric layer, which includes primarily a silicon oxide material. For example, the selectivity of the etching process is afforded by the layers that are surrounding the polysilicon layer that is to be etched away (e.g., the gate structure and the substrate together provide alignment for the etching). The undercut region is a void region as defined by the gate dielectric thickness in a specific embodiment, as shown. It is to be appreciated that using the self-limiting etching process as described above, the need for using photoresist is removed, thus, allowing for the device to be further scaled down compared to conventional processes.

In FIG. 6, the etching process can be a wet dielectric etch process, e.g., an HF solution for etching silicon oxide. Alternatively, an isotropic dry etch process suitable for etching the gate dielectric layer can be used. In a specific embodiment, the thin gate dielectric limits the transport of etchant chemicals and etch residues, thereby causing the etch process to be substantially self-limiting. In an embodiment, this is a self-aligned etch process, no lithographic process or photoresist is needed. As a result, the device dimension is not subject to the limitations of the lithographic patterning process. For example, the width of the remaining gate dielectric can be smaller than the minimum geometry allowed in the lithographic process. Further, the width of the undercut region can also be made to be smaller than the minimum geometry. As a specific example, the width of the gate dielectric can be that allowed by the minimum geometry, and the undercut regions and the remaining gate dielectric can all be smaller than the minimum geometry. Therefore, a minimum geometry twin-bit memory cell can be formed using this method, enabling a high density memory device. In an embodiment, the undercut region 602 has a width of about 200 angstroms to about 1000 angstroms and a depth of 150 angstroms to about 600 angstroms. The height of the undercut region is substantially equal the thickness of the gate dielectric layer, which can be from about 50 angstroms to about 1000 angstroms in a specific embodiment.

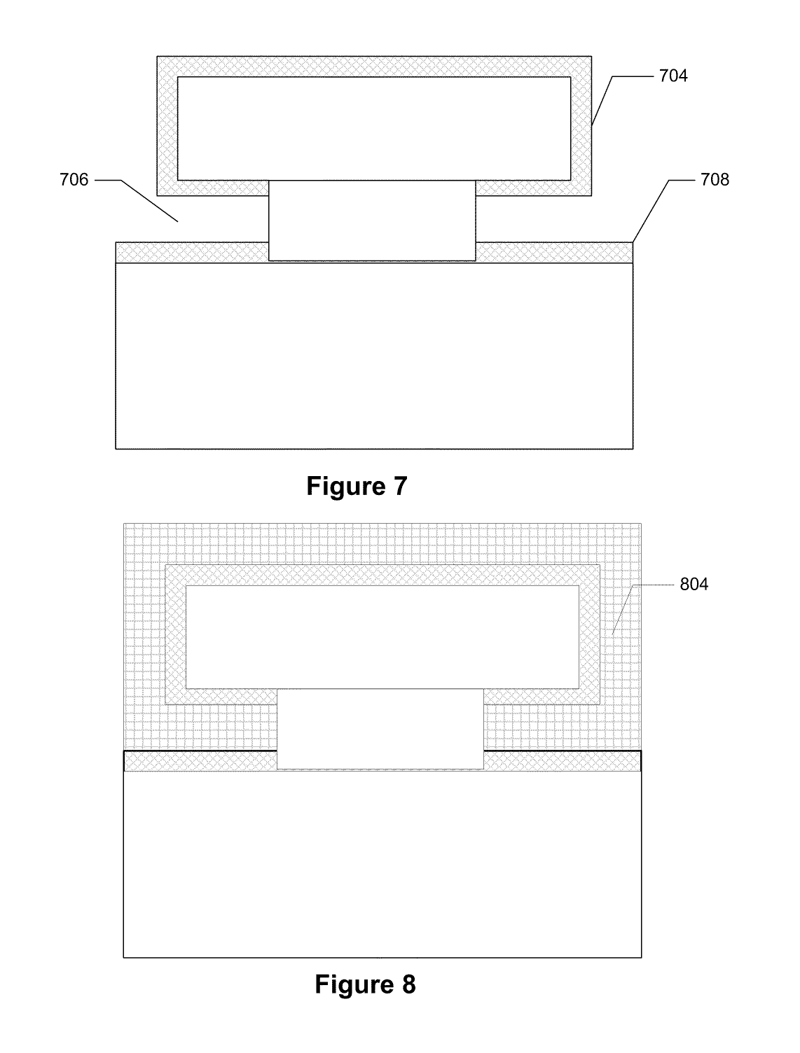

In a specific embodiment, the method includes subjecting the polysilicon gate structure to an oxidizing environment to form an oxide layer 704 as illustrated in FIG. 7. The oxidizing environment causes a first silicon oxide layer 704 to form overlying a portion of the polysilicon gate. For example, the first silicon oxide layer 704 includes oxide formed polysilicon material that is doped with N-type impurities. The oxidizing environment also causes a second undercut region 706 to form between the polysilicon gate structure and the surface of the substrate. As shown, a thin silicon oxide layer 708 is also formed overlying the surface region of the semiconductor substrate. For example, the silicon oxide layer 708 contains primarily oxide formed with the doped (P-type) single silicon material. In an embodiment, the first silicon oxide layer has a thickness ranging from about 20 angstroms to about 300 angstroms. Of course, there can be other variations, modifications, and alternatives.

In a specific embodiment, the method includes forming an undoped polysilicon material 804 overlying a peripheral region of the polysilicon gate structure, the thin oxide layer and filling the second undercut region as shown in FIG. 8. In a specific embodiment, the undoped polysilicon material 804 is deposited using chemical vapor deposition technique. For example, the undoped polysilicon material 804 is formed by subjecting the device to silane (i.e., SiH₄) gas to a temperature of about 500 to 600 degrees Celsius at low pressure. Depending on the applications, other types of deposition techniques and gaseous species may be used. For example, silane gas may be used together with hydrogen species (e.g., H₂) for the purpose of depositing undoped polysilicon material 804. As shown, the undoped polysilicon material 804 fills the undercut region between the gate and the substrate. As shown in FIG. 8, the embodiment of the present invention provides that the thickness of the undoped polysilicon material is controlled by the thickness of the gate oxide material. In a specific embodiment, the undoped polysilicon material has charge trapping capability to receive and store charges injected into the undoped polysilicon material. Of course, there can be other variations, modifications, and alternatives.

FIG. 9 is a simplified diagram exemplified an embodiment of the present invention. As shown, the method performs a selective etching process to remove a first portion of the undoped polysilicon material from the gate structure while maintaining the undoped polysilicon material in an insert region 904 within the undercut region. In a specific embodiment, reactive ion etching (RIE) process is used to remove a portion of the undoped polysilicon material. For example, a void region 906 is formed after portions of the undoped polysilicon material are removed with the RIE process. As an example, the device is placed in essentially a vacuum chamber for the etching process. As shown in FIG. 9, the structure 902 can be used to provide necessary alignment for the selective etching process. The undoped polysilicon material in the insert region provides a double side structure with a twin bit function for the memory device in a specific embodiment. For example, the undoped polysilicon material on each side can be adapted to hold charges, thereby each can provide a bit of memory. The undoped polysilicon material on each side is separated by an insulating layer, thereby preventing one charge from interfering with the other. Of course, there can be other variations, modifications, and alternatives.

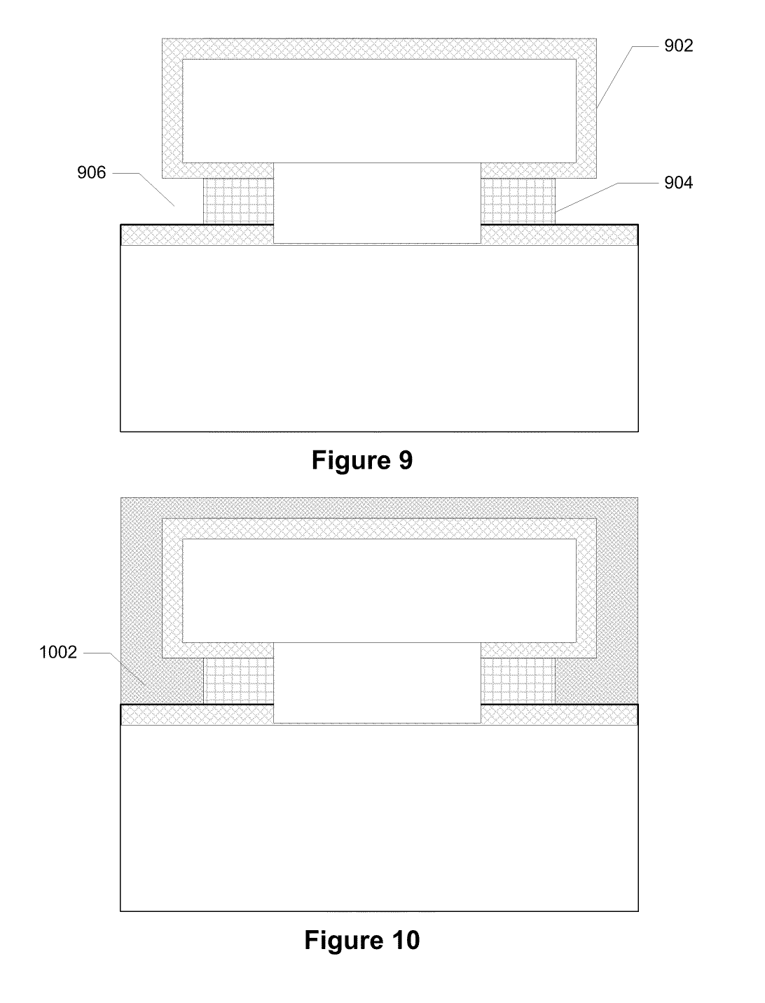

Referring to FIG. 10, the method includes forming a conformal dielectric layer 1002 overlying the polysilicon gate structure and exposed portions of the insert regions. The conformal dielectric layer can be formed by oxidizing the undoped polysilicon material. The conformal dielectric layer may also be a composite stack such as a silicon oxide on silicon nitride on silicon oxide (or commonly known as SONOS) depending on the embodiment.

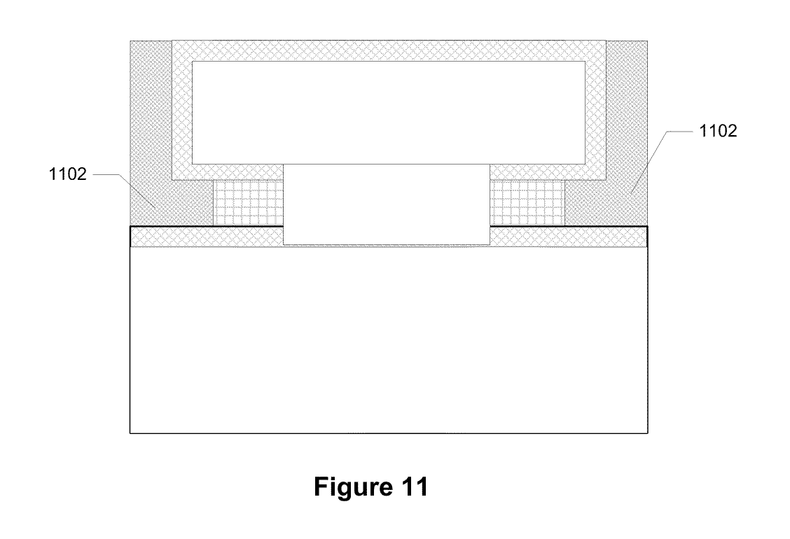

Referring to FIG. 11, the method includes performing a selective etching process to remove a portion of the dielectric layer 1002, thus, forming sidewall spacer structures 1102 and exposing the top portion of the polysilicon gate structure. The sidewall spacer structures 1102 is used to insulate the sides of the polysilicon gate structure and to expose portions of undoped polysilicon material in the insert regions. The sidewall spacer structure isolate and protect the polysilicon gate structure in a specific embodiment.

It is to be appreciated that various steps and structures associated with the processed described above can be modified, added, removed, repeated, replaced, and/or overlapped. In a specific embodiment, an implantation process is performed to introduce As into an active region of the device. For example, As can be used to function as N-type dopant.

According to another embodiment, the present invention provides a non-volatile memory device. A specific example of the non-volatile memory device is shown in FIG. 11. In an embodiment, the non-volatile memory device includes a semiconductor substrate including a surface region, a gate dielectric layer overlying the surface region, a polysilicon gate structure overlying the gate dielectric layer. The non-volatile memory device also has a first undercut region underneath the polysilicon gate structure in a portion of the gate dielectric layer and a first silicon oxide layer covering an underside of the polysilicon gate structure facing the undercut region. Moreover, the non-volatile memory device also includes an undoped polysilicon material in an insert region in a portion of the undercut region and a sidewall structure overlying a side region of the polysilicon gate structure and a side region of the undoped polysilicon material.

In an embodiment of the non-volatile memory device, the first silicon oxide layer includes oxidized polysilicon material. In another embodiment, the first silicon oxide layer is formed by oxidizing the polysilicon gate structure. In another embodiment, the non-volatile memory device also includes a second silicon oxide layer overlying a surface region of the semiconductor substrate facing the undercut region. In another embodiment, the non-volatile memory device further includes a second undercut region at least partially filled with the undoped polysilicon material. In another embodiment, the polysilicon gate structure is characterized by a width defined by the minimum geometry of a patterning process.

Although specific embodiments of the present invention have been described, it will be understood by those of skill in the art that there are other embodiments that are equivalent to the described embodiments. Accordingly, it is to be understood that the invention is not to be limited by the specific illustrated embodiments, but only by the scope of the appended claims.

What is claimed is:

1. A method for forming a non-volatile memory structure, the method comprising:
providing a semiconductor substrate including a surface region;
forming a gate dielectric layer overlying the surface region;
forming a polysilicon gate structure overlying the gate dielectric layer;
forming an undercut region underneath the polysilicon gate structure in a portion of the gate dielectric layer;
subjecting the polysilicon gate structure to an oxidizing environment to cause formation of a first silicon oxide layer overlying a periphery of the polysilicon gate structure;
forming an undoped polysilicon material overlying the polysilicon gate structure filling the undercut region;
subjecting the undoped polysilicon material to a selective etching process while maintaining the undoped polysilicon material in an insert region in a portion of the undercut region; and
forming a sidewall structure overlying a side region of the polysilicon gate structure.

2. The method of claim 1 further comprising forming a source region and a drain region.

3. The method of claim 1, wherein the sidewall spacer structure is formed by subjecting the undoped polysilicon material to an oxidation process.

4. The method of claim 1, wherein the semiconductor substrate is a P-type silicon wafer.

5. The method of claim 1, wherein the undercut region is formed using a self-limiting etching process.

6. The method of claim 1 wherein the undercut region is a void region.

7. The method of claim 1, wherein forming an undoped polysilicon material comprises performing chemical vapor deposition processing at a temperature of approximate 400 to 500 degrees Celsius.

8. The method of claim 1, wherein the undoped polysilicon material is formed using silane compound.

9. The method of claim 8, wherein the silane compound has a chemical formula of SiH₄.

10. The method of claim 1, wherein the insert regions provide a double-sided bit structure.

11. The method of claim 1, wherein the undoped polysilicon material is characterized by a first thickness, the first thickness being controlled by a thickness of the gate dielectric layer.

12. The method of claim 1 further comprises forming active regions in a vicinity of the surface region of the semiconductor substrate.

13. The method of claim 12, wherein the active regions are formed by an implantation process using a N type arsenic as an impurity species and the polysilicon gate structure, including the sidewall spacer as a mask.

14. The method of claim 1, wherein the selective etching process comprises a reactive ion etching process.

15. A non-volatile memory device, comprising:
a semiconductor substrate including a surface region;
a gate dielectric layer overlying the surface region;
a polysilicon gate structure overlying the gate dielectric layer;
a first undercut region underneath the polysilicon gate structure in a portion of the gate dielectric layer;
a first silicon oxide layer covering an underside of the polysilicon gate structure facing the undercut region;
an undoped polysilicon material in an insert region in a portion of the undercut region; and
a sidewall structure overlying a side region of the polysilicon gate structure and a side region of the undoped polysilicon material.

16. The memory device of claim 15, wherein the first silicon oxide layer comprises oxidized polysilicon material.

17. The memory device of claim 15, wherein the first silicon oxide layer is formed by oxidizing the polysilicon gate structure.

18. The memory device of claim 15 further comprising a second silicon oxide layer overlying a surface region of the semiconductor substrate facing the undercut region.

19. The memory device of claim 15 further comprising a second undercut region at least partially filled with the undoped polysilicon material.

20. The memory device of claim 15, wherein the polysilicon gate structure is characterized by a width defined by the minimum geometry of a patterning process.
